(19) United States
(12) Patent Application Publication
(10) Pub. No.: US 2014/0285121 A1
(43) Pub. Date: Sep. 25, 2014

(54) MODULATION SCHEME FOR DRIVING A PIEZO ELEMENT

(71) Applicant: Fairchild Semiconductor Corporation, San Jose, CA (US)

(72) Inventors: Laszlo Balogh, Merrimack, NH (US); Daniel Robert Slater, Reading (GB)

(21) Appl. No.: 14/355,874

(22) PCT Filed: Nov. 7, 2012
(86) PCT No.: PCT/US12/63794

§ 371 Date: May 2, 2014

Related U.S. Application Data
(60) Provisional application No. 61/557,142, filed on Nov. 8, 2011.

(51) Int. Cl. H01L 41/04

(52) U.S. Cl. CPC H01L 41/042
USPC 318/116; 310/316.01

(57) ABSTRACT

The present disclosure is directed to a modulation scheme for driving a piezo element. In one embodiment, a device may comprise, for example, a piezo element, voltage rails and bridge circuitry. The bridge circuitry may be coupled between the piezo element and the voltage rails. The bridge circuitry may include at least signal sources configured to generate drive signals that cause the piezo element to generate mechanical movement while being coupled to at least one of the voltage rails. In the same or a different embodiment the bridge circuitry may further include comparators, the output of the comparators being usable to determine the resonant frequency of the piezo element. The operating frequency of the bridge circuitry may be configured based on the resonant frequency of the piezo element.

### PRIORITY

The present U.S. Patent Application claims priority to U.S. Provisional Patent Application No. 61/557,142 entitled “IMPROVED MODULATION SCHEME TO DRIVE PIEZO RESONATORS” filed on Nov. 8, 2011, the contents of the above parent application being incorporated herein, in entirety, by reference.

### TECHNICAL FIELD

The present invention relates to electromechanical systems, and more specifically, to a system for causing mechanical movement in a piezo element.

### BACKGROUND

Piezo elements (e.g., piezo resonators) may be used to generate mechanical movement using electrical energy. For example, mechanical movement may be generated by applying a time-varying electrical potential (e.g., an alternating current (AC) voltage) to the piezo element. FIG. 1 illustrates example bridge circuitry that may be used to drive a piezo element. The bridge circuitry includes transistors (e.g., MOSFETS) Q1, Q2, Q3 and Q4 configured to apply a positive voltage signal, a negative voltage signal or no voltage signal (e.g., no excitation) across the piezo element based on the VPE voltage polarity shown across the piezo element in FIG. 1. Typically, the pulse width of the drive signals generated by signal sources A, B, C and D are the same.

In one example of operation, voltage may be applied in the positive direction across the piezo resonator by turning on the B and C drive signal sources, followed by a state when all four signal sources (A, B, C and D) are off. Then a negative voltage may be applied by turning on A and B drive signal sources followed by a state when all four drive signal sources are again off. In the disclosed implementation, the repetition rate of the above signal source activation pattern should match the mechanical resonant frequency of the piezo resonator, which has a relatively large tolerance due to the mechanical tolerances of its manufacturing process.

### BRIEF DESCRIPTION OF THE DRAWINGS

Reference should be made to the following detailed description which should be read in conjunction with the following figures, wherein like numerals represent like parts:

FIG. 1 illustrates a prior art circuit diagram;

FIG. 2 illustrates example input drive signals associated with an example piezo resonator drive methodology consistent with the present disclosure;

FIG. 3 illustrates example output drive waveforms associated with the example piezo resonator drive methodology disclosed in FIG. 2;

FIG. 4 illustrates an example drive circuit diagram for a piezo resonator including feedback consistent with the present disclosure;

FIG. 5 illustrates example comparator waveforms associated with a modulation scheme including feedback consistent with the present disclosure; and

FIG. 6 illustrates example operations related to a modulation scheme for driving a piezo element consistent with the present disclosure.

Although the following Detailed Description will proceed with reference being made to illustrative embodiments, many alternatives, modifications and variations thereof will be apparent to those skilled in the art.

### DETAILED DESCRIPTION

The present disclosure is directed to a modulation scheme for driving a piezo element. In one embodiment, a device may comprise, for example, a piezo element, voltage rails and bridge circuitry. The bridge circuitry may be coupled between the piezo element and the voltage rails. The bridge circuitry may include at least signal sources configured to generate drive signals that cause the piezo element to generate mechanical movement while being coupled to at least one of the voltage rails.

The piezo element may be, for example, a piezo resonator. The bridge circuitry may also comprise four transistors and four signal sources, the gate of each of the transistors being coupled to a signal source. Two of the four signal sources may be configured to generate drive signals that alternate in causing either a positive terminal of the piezo element to be coupled to a low voltage rail or a negative terminal of the piezo element to be coupled to the low voltage rail. The other two signal sources may be configured to generate drive signals including energizing pulses that cause the positive terminal of the piezo element to be coupled to a high voltage rail when the negative terminal of the piezo element is coupled to the low voltage rail and cause the negative terminal of the piezo element to be coupled to the high voltage rail when the positive terminal of the piezo element is coupled to the low voltage rail.

In one embodiment, the bridge circuitry may further comprise comparators configured to generate signals indicative of the resonant frequency of the piezo element. For example, a first comparator may be configured to compare the voltage at the positive terminal of the piezo element to a reference voltage, while a second comparator is configured to compare the voltage at the negative terminal of the piezo element to the reference voltage. In the same or a different embodiment, a processor in the device (e.g., included within or coupled to the bridge circuitry) may be configured to determine the resonant frequency of the piezo element based on signals output from the first comparator and the second comparator. For example, the processor may be configured to determine a leading edge of a resonant period based on the signal output from the first comparator and a trailing edge of the resonant period based on the signal output from the second comparator. The processor may then be configured to configure the bridge circuitry (e.g., to configure the signal sources) based on the resonant frequency.

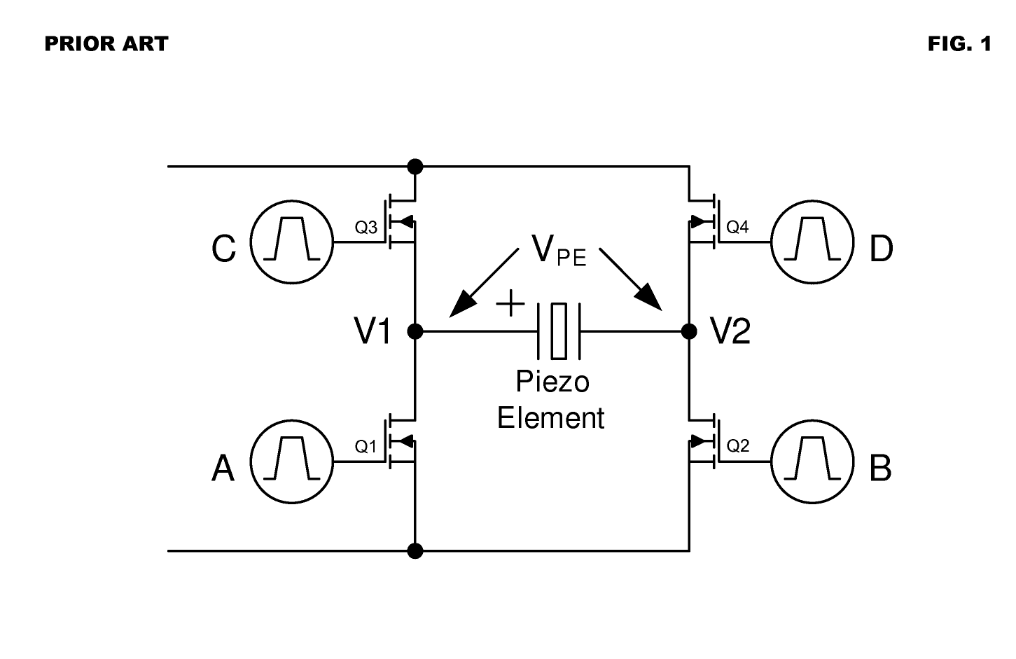

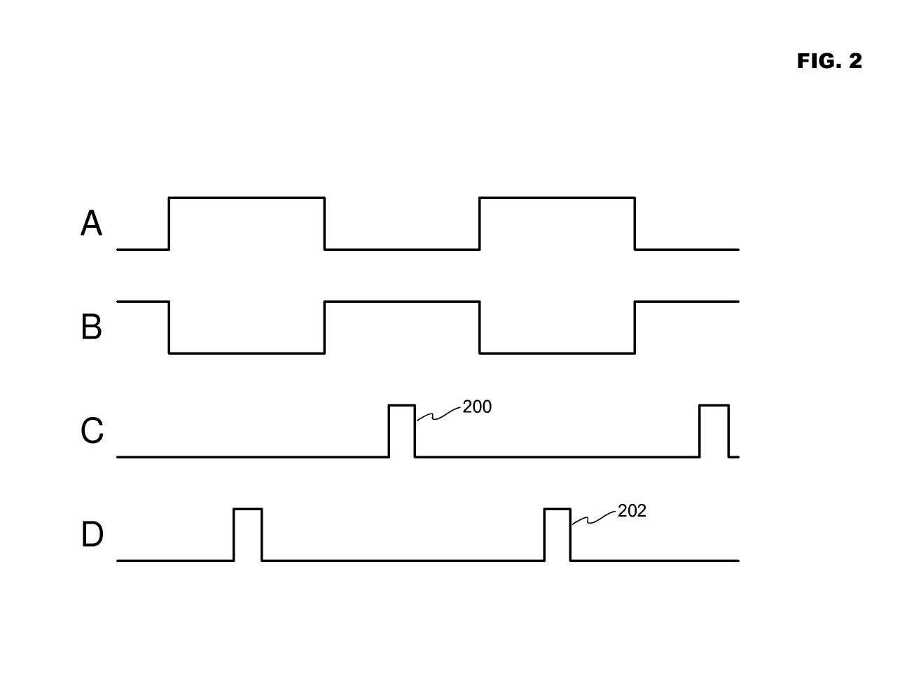

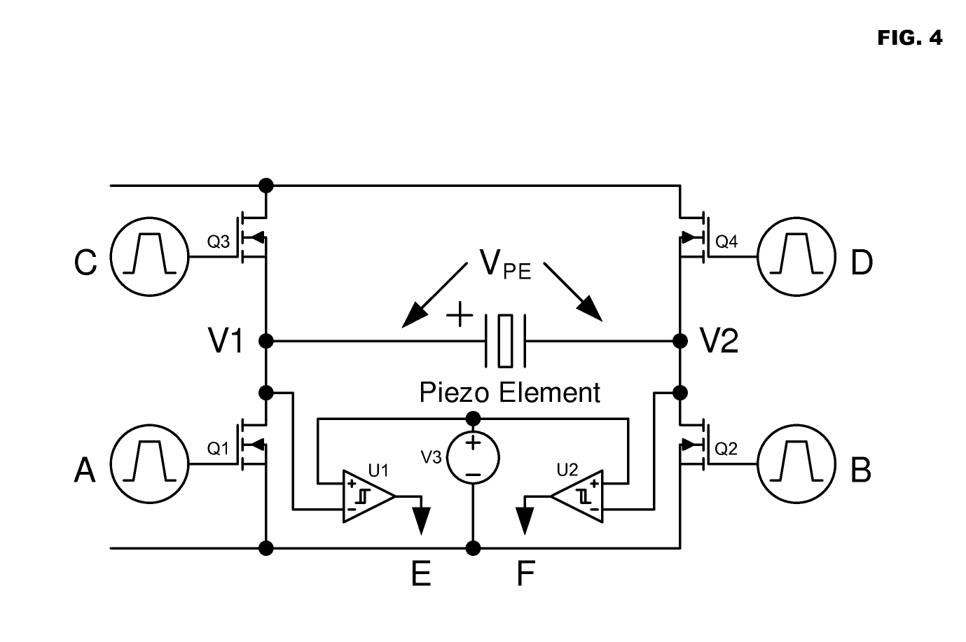

FIG. 2 illustrates example input drive signals associated with an example piezo resonator drive methodology consistent with the present disclosure. In one embodiment, control signals A, B, C and D may be configured to drive the piezo element in a manner that never allows the piezo element to “float” or become disconnected from an input voltage rail (e.g., the high voltage rail may be coupled to the common drain connection of MOSFETs Q3 and Q4 and the low voltage rail may be coupled to the common source connection of MOSFETs Q1 and Q2). While it may be possible to drive the piezo element using complimentary 50% duty cycle signals wherein, for example, drive signals A=D and B=C, this is an inefficient “brute force” method. For example, keeping the piezo practically grounded through MOSFET Q1 or Q2 may allow the mechanical resonance and resulting induced voltage in the piezo element to be harnessed to charge/discharge the output capacitances of the MOSFETS Q1-Q4 in the bridge circuitry, resulting in much more efficient switching. Moreover, using a scheme such as disclosed herein that prevents the piezo element from floating also makes possible the enhanced bridge circuitry described in FIG. 4-6 wherein operational characteristics of the piezo element may be determined and used to tune the bridge circuitry, which would otherwise be very difficult to implement. As illustrated in FIG. 2, control signals A and B may be, for example, approximately 50% duty ratio complementary square waves configured to alternate between coupling terminal V1 or V2 of the piezo element to the negative input rail via transistors Q1 and Q2, respectively. In one embodiment, the actual excitation of the piezo element may occur by turning on drive signal C while the drive signal B is active as shown at 200. In this phase a positive voltage will be applied across the piezo element according to the VPE polarity illustrated in FIG. 1. For example, drive signal C may be a short pulse positioned approximately in the middle of the active state of control signal B. To apply the negative polarity across the piezo element, drive signal D may be activated while drive signal A is active, as shown at 202, in a similar manner as was explained with respect to the drive signals B and C. In this scheme, the repetition rates of all four drive signals may match the mechanical resonant frequency of the piezo element. To understand the benefits of this modulation scheme, the resulting voltage waveforms of the bridge circuit should be analyzed (e.g., V1, V2 and VPE).

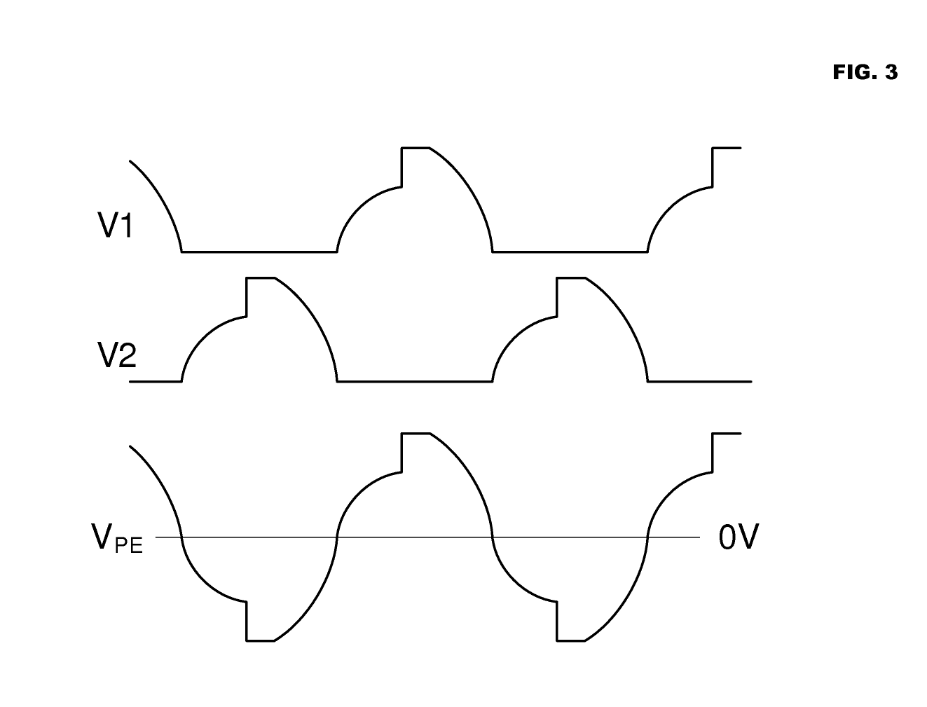

FIG. 3 illustrates example output drive waveforms associated with the example piezo resonator drive methodology disclosed in FIG. 2. In one embodiment, drive signals A and D being active at the same time forces a negative voltage across the piezo element. The negative voltage induces a flexion in the piezo element, moving it out of its steady, neutral state. Then, for example, control signal D may be terminated while control signal A remains active, causing voltage V2 to follow a resonant waveform from the positive bias rail towards the negative bias rail as shown in FIG. 3. The amplitude of voltage V2 may be proportional to the flexion in the piezo element. The piezo element returning to its neutral state then causes voltage V2 voltage to fall. Voltage V2 becomes zero when the piezo element is back to its steady state mechanical shape. At or around this moment, drive signal A may be terminated and drive signal B may be activated. The benefit of this switching sequence is that MOSFET Q2 (e.g., connected to the source of signal B) may be turned on with 0V across its drain-source terminals, and thus the circuit may operate with zero voltage switching, reducing the losses in the drive bridge circuit.

Due to mechanical inertia, the piezo element will flex in the other direction and induce a positive voltage across its terminals. Since drive signal B is active and drive signal A is off, the mechanically induced voltage will force voltage V1 to start resonating from the negative rail towards the positive input rail. Utilizing this mechanical inertia and its reflected voltage across the piezo element, voltage V1 increases. In one embodiment, drive signal C may be activated when voltage V1 reaches its maximum value. At that point MOSFET Q3 (e.g., connected to the source of signal C) may be turned on with minimum losses. While control signal C is active (e.g., along control with signal B) a positive voltage is forced across the piezo element forcing it to move further out of its mechanical equilibrium point, exiting the mechanical resonance for the other direction (e.g., with respect to the negative voltage applied by B and C). After drive signal C is deactivated, the process may be repeated in a symmetrical manner for the voltage V1. For example, voltage V1 will resonate from the positive rail to the negative input rail. When voltage V1 nears 0, drive signal A may be deactivated and drive signal B may be activated, facilitating zero voltage switching for MOSFET Q2 connected to the source of drive signal B. Voltage V2 may then start to rise following the reflected voltage from the piezo element and minimizing the voltage across MOSFET Q4 (e.g., connected to the source of signal D) when it is turning on.

The example embodiment disclosed above may help to ensure zero voltage switching for MOSFETs Q1 and Q2 and may minimize the voltage across the MOSFETs Q3 and Q4 at their turn on instance. Operating under these conditions may provide better efficiency for the bridge circuitry and may reduce the EMI noise footprint of the circuit by making use of the naturally occurring resonant waveforms created by driving the piezo element such as described above.

A further extension of the modulation scheme may utilize two additional comparator circuits for feedback. FIG. 4 illustrates an example drive circuit diagram for a piezo resonator including feedback consistent with the present disclosure. Comparators U1 and U2 may be used to facilitate tuning of the frequency of the control signals controlling the operating frequency of the piezo driver circuitry (e.g., the bridge circuitry). As explained above, the bridge circuitry is required to operate at the frequency of the mechanical resonant frequency of the piezo element. Since the mechanical resonant frequency cannot be tightly controlled, it is desirable to provide a mechanism that allows the actual resonant frequency to be determined in situ, and the operating frequency of the bridge circuitry to be tuned the actual resonant frequency of the piezo element. In one embodiment, using comparators U1 and U2 along with the proposed drive scheme makes it possible to “learn” the mechanical resonance of the piezo element and to tune the operating frequency of the bridge circuitry based on the mechanical resonance.

In the embodiment disclosed in FIG. 4, the comparators U1 and U2 are used as voltage detectors. For example, voltage V1 may be coupled to the non-inverting input of comparator U1 while the inverting input may be coupled to voltage V3 (e.g., threshold voltage). When voltage V1 reaches the threshold voltage, the output of comparator U1 may transition from low to high (e.g., producing signal E). This transition may be used to, for example, terminate drive signal B and activate drive signal A. Similarly, voltage V2 may be coupled to the non-inverting input of comparator U2, which may also be coupled to threshold voltage V3. When voltage V2 crosses the threshold voltage, the output of comparator U2 may generate a rising edge (e.g., signal F) that may be used to, for example, terminate control signal A and activate control signal B.

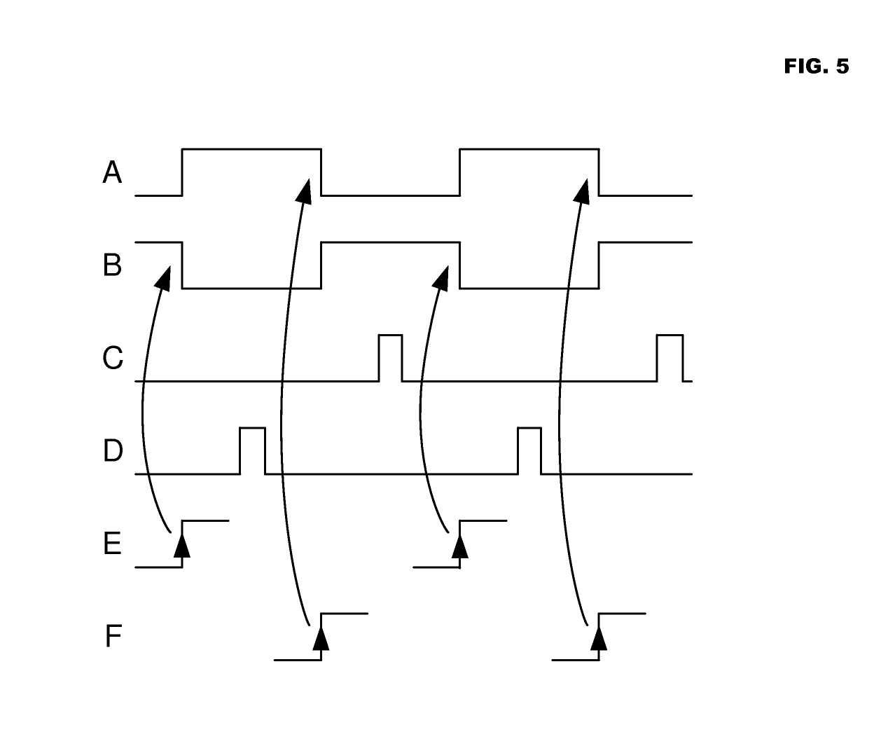

FIG. 5 illustrates example comparator waveforms associated with a modulation scheme including feedback consistent with the present disclosure. In one embodiment, the outputs of comparators U1 (signal E) and U2 (signal F) may be used to determine the resonant frequency of the piezo element, which allows the operating frequency of the bridge circuitry to be configured. FIG. 5 shows how rising edges in signals E and F may be used to determine resonant frequency for the piezo element. For example, a leading edge of a resonant period may be indicated by a rising edge in signal E (e.g., the output of comparator Q1) and a trailing edge of the resonant period may be indicated by a rising edge in signal F (e.g., in the output of comparator Q2).

In operation, a learning algorithm to match the piezo driver bridge's operating frequency to the actual resonant frequency of the piezo element may be implemented using either analog or digital control methods. In one embodiment, a processor may be incorporated within, or may be coupled to, the bridge circuitry and may be configured to determine the resonant frequency and to configure the operating frequency of the bridge circuitry. For example, a microcontroller, digital signal processor (DSP), state machine-based solution, etc. having time awareness and measurement abilities may be used for implementation (e.g., a device having a clock signal to establish a time base, a counter and general purpose input/output (GPIO) to receive signals from comparators U1 and U2). Since the outputs of comparators U1 and U2 are fundamentally digital signals, and positioning of the energizing pulses in drive signals C and D requires only simple time measurements, this technique may be advantageous for use in digital implementations.

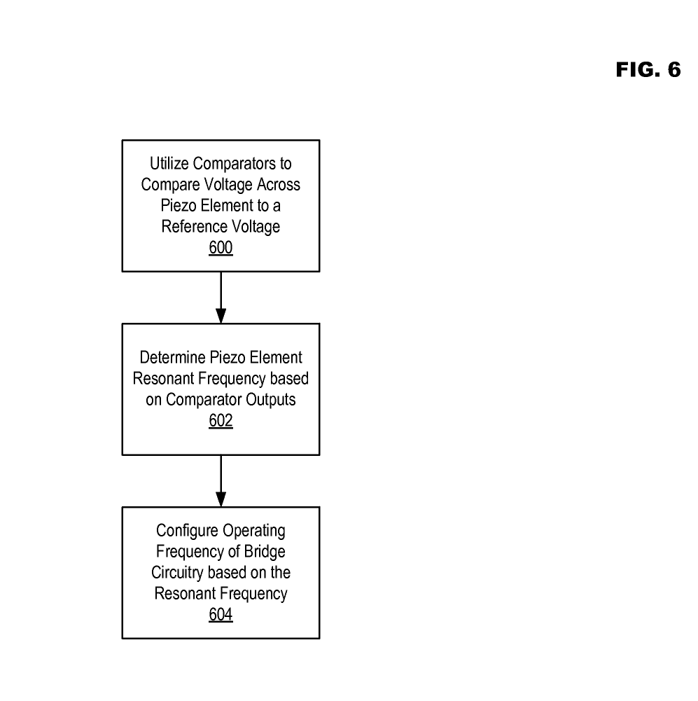

FIG. 6 illustrates example operations related to a modulation scheme for driving a piezo element consistent with the present disclosure. In operation 600, comparators may be employed in comparing the voltage across the piezo element to a reference voltage. The output signals of the comparators may then be used to determine the resonant frequency of the piezo element in operation 602 (e.g., such as in the example disclosed in FIG. 5). The resonant frequency of the piezo element may then be used to configure the operating frequency of the bridge circuitry in operation 604. For example, after the operating frequency of the bridge circuitry is established, simple timing circuits may be used as sources for drive signals A-D. For example, the timing circuits may be configured to generate energizing pulses in drive signals C and D at instances during active periods in drive signals A and B. For example, the energizing pulses in signals D and C may be configured to occur in the middle of the active periods of drive signals A and B, respectively.

“Circuitry” or “circuit”, as used in any embodiment herein, may comprise, for example, singly or in any combination, hardwired circuitry, programmable circuitry, state machine circuitry, and/or circuitry available in a larger system, for example, discrete elements that may be included as part of an integrated circuit. In addition, any of the switch devices described herein may include any type of known or after-developed switch circuitry such as, for example, MOS transistors, BJTs, etc.

Any of the operations described herein may be implemented in a system that includes one or more storage mediums having stored thereon, individually or in combination, instructions that when executed by one or more processors perform the methods. Here, the processor may include, for example, a server CPU, a mobile device CPU, and/or other programmable circuitry. Also, it is intended that operations described herein may be distributed across a plurality of physical devices, such as processing structures at more than one different physical location. The storage medium may include any type of tangible medium, for example, any type of disk including hard disks, floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, Solid State Disks (SSDs), embedded multimedia cards (eMMCs), secure digital input/output (SDIO) cards, magnetic or optical cards, or any type of media suitable for storing electronic instructions. Other embodiments may be implemented as software modules executed by a programmable control device.

Thus, the present disclosure is directed to a modulation scheme for driving a piezo element. In one embodiment, a device may comprise, for example, a piezo element, voltage rails and bridge circuitry. The bridge circuitry may be coupled between the piezo element and the voltage rails. The bridge circuitry may include at least signal sources configured to generate drive signals that cause the piezo element to generate mechanical movement while being coupled to at least one of the voltage rails. In the same or a different embodiment the bridge circuitry may further include comparators, the output of the comparators being usable to determine the resonant frequency of the piezo element. The operating frequency of the bridge circuitry may be configured based on the resonant frequency of the piezo element. In one example embodiment there is provided a device. The device may include a piezo element, voltage rails configured to supply a voltage, and bridge circuitry coupled between at least the piezo element and the voltage rails, the bridge circuitry including at least signal sources configured to generate drive signals that cause the piezo element to generate mechanical movement while being coupled to at least one of the voltage rails.

The above example device may be further configured, wherein the piezo element is a piezo resonator.

The above device may be further configured, alone or in combination with the above configurations, wherein the bridge circuitry comprises four transistors and four signal sources, the gate of each of the four transistors being coupled to a signal source. In this configuration the example device may be further configured, wherein two of the four signal sources are configured to generate drive signals that alternate in causing either a positive terminal of the piezo element to be coupled to a low voltage rail or a negative terminal of the piezo element to be coupled to the low voltage rail. In this configuration the example device may be further configured, wherein two of the four signal sources are configured to generate drive signals including energizing pulses that cause the positive terminal to be coupled to a high voltage rail when the negative terminal is coupled to the low voltage rail and cause the negative terminal to be coupled to the high voltage rail when the positive terminal is coupled to the low voltage rail. In this configuration the example device may be further configured, wherein the bridge circuitry further comprises at least comparators configured to generate signals indicative of the resonant frequency of the piezo element. In this configuration the example device may be further configured, wherein a first comparator is configured to compare the voltage at the positive terminal to a reference voltage and a second comparator is configured to compare the voltage at the negative terminal to the reference voltage. In this configuration the example device may further comprise a processor coupled to at least the bridge circuitry, the processor being configured to determine the resonant frequency of the piezo element based on signals output from the first comparator and the second comparator. In this configuration the example device may be further configured, wherein the processor is configured to determine a leading edge of a resonant period based on the signal output from the first comparator and a trailing edge of the resonant period based on the signal output from the second comparator. In this configuration the example device may be further configured, wherein the processor may be configured to configure the signal sources based on the resonant frequency.

In another example embodiment there is provided a method. The method may comprise determining a resonant frequency for a piezo element based on signals output by comparators in bridge circuitry coupled to the piezo element, and configuring an operating frequency of the bridge circuitry based on the resonant frequency.

The above example method may be further configured, wherein determining a resonant frequency comprises determining a leading edge of a resonant period based on the signal output from a first comparator and a trailing edge of the resonant period based on the signal output from a second comparator.

The above example method may be further configured, either alone or in combination with the above configurations, wherein configuring an operating frequency of the bridge circuitry comprises configuring signal sources to generate drive signals that cause the piezo element to generate mechanical movement while being coupled to at least one voltage rail from voltage rails configured to supply a voltage to the bridge circuitry. In this configuration the example method may be further configured, wherein configuring signal sources comprises configuring two signal sources to generate drive signals that alternate in causing either a positive terminal of the piezo element to be coupled to a low voltage rail or a negative terminal of the piezo element to be coupled to the low voltage rail based on the resonant frequency. In this configuration the example method may be further configured, wherein configuring signal sources comprises configuring two signal sources to generate drive signals including energizing pulses that cause the positive terminal to be coupled to a high voltage rail when the negative terminal is coupled to the low voltage rail and cause the negative terminal to be coupled to the high voltage rail when the positive terminal is coupled to the low voltage rail.

In another example embodiment there is provided a system. The system may include means for determining a resonant frequency for a piezo element based on signals output by comparators in bridge circuitry coupled to the piezo element, and means for configuring an operating frequency of the bridge circuitry based on the resonant frequency.

The above example system may be further configured, wherein determining a resonant frequency comprises determining a leading edge of a resonant period based on the signal output from a first comparator and a trailing edge of the resonant period based on the signal output from a second comparator.

The above example system may be further configured, alone or in combination with the above configurations, wherein configuring an operating frequency of the bridge circuitry comprises configuring signal sources to generate drive signals that cause the piezo element to generate mechanical movement while being coupled to at least one voltage rail from voltage rails configured to supply a voltage to the bridge circuitry. In this configuration the example system may be further configured, wherein configuring signal sources comprises configuring two signal sources to generate drive signals that alternate in causing either a positive terminal of the piezo element to be coupled to a low voltage rail or a negative terminal of the piezo element to be coupled to the low voltage rail based on the resonant frequency. In this configuration the example system may be further configured, wherein configuring signal sources comprises configuring two signal sources to generate drive signals including energizing pulses that cause the positive terminal to be coupled to a high voltage rail when the negative terminal is coupled to the low voltage rail and cause the negative terminal to be coupled to the high voltage rail when the positive terminal is coupled to the low voltage rail.

In another example embodiment there is provided at least one machine-readable storage medium having stored thereon, individually or in combination, instructions that when executed by one or more processors result in the following operations comprising determining a resonant frequency for a piezo element based on signals output by comparators in bridge circuitry coupled to the piezo element, and configuring an operating frequency of the bridge circuitry based on the resonant frequency.

The above example medium may be further configured, wherein determining a resonant frequency comprises determining a leading edge of a resonant period based on the signal output from a first comparator and a trailing edge of the resonant period based on the signal output from a second comparator.

The above example medium may be further configured, alone or in combination with the above configurations, wherein configuring an operating frequency of the bridge circuitry comprises configuring signal sources to generate drive signals that cause the piezo element to generate mechanical movement while being coupled to at least one voltage rail from voltage rails configured to supply a voltage to the bridge circuitry. In this configuration the example medium may be further configured, wherein configuring signal sources comprises configuring two signal sources to generate drive signals that alternate in causing either a positive terminal of the piezo element to be coupled to a low voltage rail or a negative terminal of the piezo element to be coupled to the low voltage rail based on the resonant frequency. In this configuration the example medium may be further configured, wherein configuring signal sources comprises configuring two signal sources to generate drive signals including energizing pulses that cause the positive terminal to be coupled to a high voltage rail when the negative terminal is coupled to the low voltage rail and cause the negative terminal to be coupled to the high voltage rail when the positive terminal is coupled to the low voltage rail.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

1. A device, comprising:
a piezo element;
voltage rails configured to supply a voltage; and
bridge circuitry coupled between at least the piezo element and the voltage rails, the bridge circuitry including at least signal sources configured to generate drive signals that cause the piezo element to generate mechanical movement while being coupled to at least one of the voltage rails.

2. The device of claim 1, wherein the piezo element is a piezo resonator.

3. The device of claim 1, wherein the bridge circuitry comprises four transistors and four signal sources, the gate of each of the four transistors being coupled to a signal source.

4. The device of claim 3, wherein two of the four signal sources are configured to generate drive signals that alternate in causing either a positive terminal of the piezo element to be coupled to a low voltage rail or a negative terminal of the piezo element to be coupled to the low voltage rail.

5. The device of claim 4, wherein two of the four signal sources are configured to generate drive signals including energizing pulses that cause the positive terminal to be coupled to a high voltage rail when the negative terminal is coupled to the low voltage rail and cause the negative terminal to be coupled to the high voltage rail when the positive terminal is coupled to the low voltage rail.

6. The device of claim 4, wherein the bridge circuitry further comprises at least comparators configured to generate signals indicative of the resonant frequency of the piezo element.

7. The device of claim 6, wherein a first comparator is configured to compare the voltage at the positive terminal to a reference voltage and a second comparator is configured to compare the voltage at the negative terminal to the reference voltage.

8. The device of claim 7, further comprising a processor coupled to at least the bridge circuitry, the processor being configured to determine the resonant frequency of the piezo element based on signals output from the first comparator and the second comparator.

9. The device of claim 8, wherein the processor is configured to determine a leading edge of a resonant period based on the signal output from the first comparator and a trailing edge of the resonant period based on the signal output from the second comparator.

10. The device of claim 9, wherein the processor is configured to configure the signal sources based on the resonant frequency.

11. A method comprising:
determining a resonant frequency for a piezo element based on signals output by comparators in bridge circuitry coupled to the piezo element; and
configuring an operating frequency of the bridge circuitry based on the resonant frequency.

12. The method of claim 11, wherein determining a resonant frequency comprises determining a leading edge of a resonant period based on the signal output from a first comparator and a trailing edge of the resonant period based on the signal output from a second comparator.

13. The method of claim 11, wherein configuring an operating frequency of the bridge circuitry comprises configuring signal sources to generate drive signals that cause the piezo element to generate mechanical movement while being coupled to at least one voltage rail from voltage rails configured to supply a voltage to the bridge circuitry.

14. The method of claim 13, wherein configuring signal sources comprises configuring two signal sources to generate drive signals that alternate in causing either a positive terminal of the piezo element to be coupled to a low voltage rail or a negative terminal of the piezo element to be coupled to the low voltage rail based on the resonant frequency.

15. The method of claim 14, wherein configuring signal sources comprises configuring two signal sources to generate drive signals including energizing pulses that cause the positive terminal to be coupled to a high voltage rail when the negative terminal is coupled to the low voltage rail and cause the negative terminal to be coupled to the high voltage rail when the positive terminal is coupled to the low voltage rail.

16-20. (canceled)

21. At least one machine-readable storage medium having stored thereon, individually or in combination, instructions that when executed by one or more processors result in the following operations comprising:
determining a resonant frequency for a piezo element based on signals output by comparators in bridge circuitry coupled to the piezo element; and
configuring an operating frequency of the bridge circuitry based on the resonant frequency.

22. The medium of claim 21, wherein determining a resonant frequency comprises determining a leading edge of a resonant period based on the signal output from a first comparator and a trailing edge of the resonant period based on the signal output from a second comparator.

23. The medium of claim 21, wherein configuring an operating frequency of the bridge circuitry comprises configuring signal sources to generate drive signals that cause the piezo element to generate mechanical movement while being coupled to at least one voltage rail from voltage rails configured to supply a voltage to the bridge circuitry.

24. The medium of claim 23, wherein configuring signal sources comprises configuring two signal sources to generate drive signals that alternate in causing either a positive terminal of the piezo element to be coupled to a low voltage rail or a negative terminal of the piezo element to be coupled to the low voltage rail based on the resonant frequency.

25. The medium of claim 24, wherein configuring signal sources comprises configuring two signal sources to generate drive signals including energizing pulses that cause the positive terminal to be coupled to a high voltage rail when the negative terminal is coupled to the low voltage rail and cause the negative terminal to be coupled to the high voltage rail when the positive terminal is coupled to the low voltage rail.
